(19) United States
(12) Patent Application Publication
(10) Pub. No.: US 2007/0201270 A1
(43) Pub. Date: Aug. 30, 2007

(54) Read only memory device with bitline leakage reduction

(75) Inventors: Kallol Chatterjee, West Bengal (IN); Vivek Asthana, Noida (IN); Jitendra Dasani, Noida (IN)

Correspondence Address: DOCKET CLERK, P.O. DRAWER 800889, DALLAS, TX, 75380, US

(73) Assignee: STMICROELECTRONICS PVT. LTD., Greater Noida (IN)

(21) Appl. No.: 11/648,155

(22) Filed: Dec. 29, 2006

(30) Foreign Application Priority Data
Dec. 30, 2005 (IN) 3533/DEL/2005

(51) Int. Cl. G11C 16/04

(52) U.S. Cl. 365/185.05

(57) ABSTRACT

A memory chip configuration aims that reduces the bitline leakage in standby as well as dynamic operation mode. The chip design comprises of—a n×m FET matrix, vertically running bitlines—each shared by a column in the array, horizontally running wordlines—each shared by a row in the array, horizontally running sourcelines—each shared by a row in the array. The sourceline signal for a row is generated by complementing the wordline signal for the same row. The memory cell read operations with the proposed configuration, substantially control the bitline leakage current thereby enhancing the memory speed by reducing the noise during read operations. Also the configuration is unconstrained by design parameters that include size and geometries of memory chips, cell densities, complexity of memory structures, fabrication technologies, etc.

### CROSS-REFERENCE TO RELATED APPLICATIONS

The present application is related to Indian Patent Application No. 3533/Del/2005, filed Dec. 30, 2005, entitled “READ ONLY MEMORY DEVICE WITH BITLINE LEAKAGE REDUCTION”. Indian Patent Application No. 3533/Del/2005 is assigned to the assignee of the present application and is hereby incorporated by reference into the present disclosure as if fully set forth herein. The present application hereby claims priority under 35 U.S.C. §119(a) to Indian Patent Application No. 3533/Del/2005.

### TECHNICAL FIELD

The present disclosure relates to reducing leakage current in Read Only Memory (ROM) cells during standby as well as dynamic mode operation.

### BACKGROUND

Read Only Memories (ROMs) are arrays comprising a structured collection of individual memory storage elements each of which is referred to as a “memory cell”. Each memory cell stores an individual data bit. ROMs are used in many LSI circuit devices. In particular, several System-On-Chip (SOC) and Application Specific Integrated Circuits (ASICs) make use of ROM memory arrays as integral elements. ROM device technology utilizes the cutting edge of semiconductor technology and is experiencing extremely rapid increase in bit-density as semiconductor technology scales down to smaller geometries. At the same time, the average ROM memory array size is increasing rapidly owing to the increasing memory requirements of SOC and ASIC devices. As a result, physical dimensions of memory arrays are shrinking rapidly while the memory cells density in each array is increasing greatly. Reduced array geometry also facilitates faster data access, which is desirable in modern memory technology and other ROM memory arrays applications.

FIG. 1 shows a conventional ROM array structure with individual memory cell units (101-106, and 115-117) arranged in “n” rows and “m” columns. All cells in a row (101, 104, 115) (102, 105, 116) (103, 106, 117) have controlled switches with their common terminals connected to corresponding common lines—SL₀, SL₁, SLn (107, 108, 109) all of which are tied to the ground potential.

The gates of all the controlled switches in a row are fed by a common, horizontally running wordline—WL₀, WL₁, . . . WLn (112, 113, 114). They all remain Non active (taken low) in Non accessing mode of ROM. Only one wordline is activated (taken high) at a time while accessing the ROM, while all others are maintained at a low level.

Similarly, the drains of all the controlled switches in a column are fed by a common, vertically running bitline—BL₀, BL₁, . . . BLm (110, 111, and 118). For cells storing a “0” the output terminal of corresponding controlled switch is connected to the bitline, whereas in cells containing a “1” the output terminal is left unconnected. When the wordline is activated the bitline of cells containing a “0” gets discharged through the controlled switch.

In one embodiment of the present disclosure, the controlled switches are NMOS transistors. The memory differentiates the data status by detecting the current flowing through the accessed cells. Ideally, when the word is not selected, the Off state current (drain to source current, I_{DS}), in cells that store a “0” should be zero, however a “leakage current” always exists in small traces and is generally referred to as sub-threshold current (I_{SUB}) or sub-threshold leakage. This current is dependent on the threshold voltage (inversely proportional), the temperature (directly proportional and increases exponentially with temp.) and the channel length of the controlled switch (inversely proportional). This leakage current can potentially interfere with the correct reading of the cell contents.

At the same time, while opting for smaller chip geometries for faster operations, the supply voltage needs to be scaled down accordingly to reduce the dynamic power consumption of integrated circuits. Consequently, to maintain performance, the threshold voltage has to be reduced proportionately. As threshold voltages get reduced, sub-threshold leakage rises exponentially. As transistor size is scaled down, sub-threshold leakage at high temperatures can compose nearly 50% of total power consumption.

Proper scaling of MOSFETs is not restricted to reduction of the gate length and width only. It involves reduction in all dimensions including the gate/source and gate/drain alignment, the oxide thickness, depletion layer widths and in turn, the substrate doping density. Each scaling methodology has its own drawbacks such as reduction in the power-delay product (Constant field scaling), velocity saturation, mobility degradation, increase in leakage currents and lower breakdown voltages (Constant voltage scaling).

Drain Induced Barrier Lowering (DIBL) is another effect that links the drain voltage, the output conductance and the threshold voltage. It occurs due to the two-dimensional field distribution at the drain end, when only the gate length is reduced without properly scaling the other dimensions. This results in the variation of the measured threshold voltage with reduced gate length and correspondingly affects sub-threshold leakage.

Thus, in the case of submicron technology, the sub-threshold current of each cell increases very significantly making it difficult to support a large number of cells connected to one bitline in the memory array. Thus, there is a need to reduce the sub-threshold leakage current in ROM cells.

In a conventional ROM, there is no complementary bitline. So to sense data there should be differential current drawn from BL or differential BL voltage drop in Read ‘0’ and Read ‘1’ cases. Hence the min. current in case of Read ‘0’ should be more than the maximum possible current drawn from bitline in case of Read ‘1’. The min current in Read ‘0’ is Ion of the accessed core transistor while other transistors connected to Bitline are programmed as ‘1’ and the maximum current in case of Read ‘1’ would be (n−1)*Ioff when all other transistors connected to that Bitline would be programmed as ‘0’. So Ion>>(n−1)*Ioff for correct and fast read operation.

In NMOS transistors, as the transistor gate length decreases, the difference between the On current (I_{ON}) of one cell and the total sub-threshold current of n−1 cells (where n=the total no. of cells connected per BL) reduces further, making the sensing difficult and leads to an incorrect read operation. Hence reducing I_{SUB} or manipulating the gap between I_{ON} and [(n−1)*I_{SUB}] values becomes important while configuring memory chips.

One solution to minimize the resultant sub-threshold leakage [(n−1)*I_{SUB}] is to reduce the number of cells (n) in a column (per BL) . However, for large arrays a hierarchical structure is required that incurs a significant area penalty and needs additional metal layers for multiple levels of bitline. In this approach, each column of the ROM array is divided into “k” local bitlines. The number of cells per BL is now “n/k”. By this arrangement one BL receives the sub-threshold current of “n/k −1” cells which results in much lower discharge of the bitline in case of ‘Read1’ than in case of ‘Read 0’. So the data levels are read/sensed accurately.

An alternate solution is to select a workable, lower ROM cell gate length so as to maintain I_{SUB} (inversely exponentially with gate length) within acceptable limits. However, increase in gate length further increases the area of the memory, as well as reduces I_{ON} —the transistor ON current. Hence the ratio I_{ON} to I_{SUB} does not improve much. The reduction in I_{ON} also slows down the memory speed performance.

A third solution utilizes the fact that the sub-threshold current depends on the threshold voltage (Vₜₕ) of the transistor (Equation 1). The I_{SUB} can be reduced by increasing the V_{TH} for the ROM cells. This can be achieved by utilizing the back bias technique (Equation 2) that involves maintaining the bulk supply at lower potential than the source of the NMOS transistors.

Equations 1 & 2 illustrate a mathematical representation of the proportionality between threshold voltage and sub-threshold leakage current and other parameters affecting them.

$$\begin{matrix}{I}_{Sub} ∝ {μ}_{eff} {C}_{ox} \frac{W}{L} {ⅇ}^{\frac{q ( {V}_{g} - {V}_{T} )}{mKT}} [ 1 - {ⅇ}^{- \frac{{qV}_{ds}}{KT}} ] & ( Eqn . 1 ) \\ {V}_{T} = {V}_{TO} + K ( \sqrt{Vbs + 2 ψ} - \sqrt{2 ψ} ) - λ Vds & ( Eqn . 2 )\end{matrix}$$

However, as the negative bulk-bias reduces I_{ON}, it is not effective in increasing the ON to OFF current ratio significantly but is more suitable to reduce the overall core leakage. Also, this approach needs additional voltage supply other than GND and VDD.

Similarly, as Vₜₕ or I_{SUB} depends on gate to source bias (V_{gs}) exponentially, reducing V_{gs} by using a negative wordline will also reduce the leakage. For the active cell, I_{ON} does not change by holding the wordlines negative for the unselected cells as it reduces their cumulative sub-threshold leakage current. However, this approach is not cost effective as it requires a separate negative supply that can sink the source current of big WL drivers and a charge pump that would generally be larger than the size of the entire memory array.

FIG. 2 is another conventional technique (described in, for example, U.S. Pat. No. 6,853,572). In this technique, the I_{SUB} reduction is achieved by sharing the source lines vertically among the columns of memory cells using a twisted source line architecture. During the standby mode, both the source line and the bitline are held at the same potential (V_{dd}) thereby minimizing I_{SUB}. During the active cycle, the wordline for the cells selected for read operation goes high while other wordlines stay low. Also, the respective source line is pulled down allowing the accessed cells to discharge the BL. The technique divides each column of memory cells into small groups (301-312).

Source lines (318, 319) are twisted vertically so as to be shared by specific groups of ROM cells (304-308-312 and 307-305-303 respectively), each group belonging to different columns in ROM array. All memory cell groups in a column (307-309) share single bitline (316) but two or more (318 & 319) twisted source lines. Memory cell is programmed to store logic ‘1’ when source and drain are connected to the same sourceline or bitline, and logic ‘0’ if source and drain go to different data lines, say—sourceline and bitline.

In standby applications, BL and SL are held at same potential—a high voltage level. During active read operation on a cell, SL (318) is pulled low and WL (313) is ON. If the read bit cell is programmed ‘1’ the BL (315) should remain ‘high’; else for the bit cell programmed as ‘0’ the BL discharges through the transistor.

Even while reading the bit cell programmed as ‘1’ the BL may not remain at high voltage state. Other bit cells programmed as ‘0’ and sharing the same BL and SL, have some cumulative leakage current bringing down the BL level to a point where it needs to be recharged. Also, the SL to BL coupling may cause adjacent BL to drop in voltage level. Using twisted SL and producing small sized groups of bit cells, these problems are reduced.

The second twisted SL (319), feeding the 2^{nd} group of cells (305) in the first column, maintains its voltage state during read operation of the cells in the first group (304). Hence there exists no leakage current for the cells in the second group as the BL1 and SL2 maintain their respective voltages. Similarly, during the read operation in the 2^{nd} group (307) of cells, the sourceline SL1 (318) maintains its voltage state avoiding leakage current from group 2 cells. The I_{SUB} value gets reduced by factor 1/n where n is the number of groups, the column is divided into.

The twisted cells (320, 321, 322) carry out geometrical displacement of source line using the metal layers and vias at the boundaries of the sections or memory cell groups.

Depending on the address of the cell selected to read, the address decoder circuitry activates the circuit to bring down the SL voltage as well as activates the WL feeding the gates of the memory cells proposed for read operation. Using a PMOS/NMOS transistor pair (323, 324) that is activated by address decoder signals, the source and bitlines are held at distinctly high/low voltage levels. The virtual ground technique is used to switch the voltage state of SL during the read operation.

In an embodiment, with twisted architecture, BL (314-317) is never twisted; two lines among SL, BL and WL run parallel and the remaining runs orthogonal. This orthogonal routing architecture requires the least number of lines and less complexity in implementation. It is advisable to have least number of lines twisted as it consumes area on the target chip. The twisted line geometry preserves the stored charge in the pre-charged bitline during a read operation on a given bit cell programmed as logic ‘1’.

This approach suffers from the limitation that the leakage current is not reduced in dynamic operation mode. Dynamic mode leakage is an important source of noise during the read operation of non-programmed cell. Also a coupling issue is seen in this kind of scheme. The selected Vertical Source line when going low gives coupling to BL and hence impacts the BL level and can lead to functional failure in case of Read ‘1’. To avoid this, the precharge-off of the BL has to be delayed which is a penalty in speed performance.

There is therefore a need for a system and method that minimizes sub-threshold leakage current in Read Only Memory (ROM) cells in both, standby and dynamic mode. In particular, there is a need for a solution that is workable within the constraints of interdependent parameters such as chip geometry—area and strategy, with no extra cost of mask layer, gate length, ON current for the cell, threshold voltage without sacrificing the benefits of their optimal values.

### SUMMARY

The present disclosure provides an arrangement for reducing the bit line (BL) leakage problems in a Read Only Memory (ROM) cell array in both the static and dynamic modes of operation. For example, in one embodiment, the present disclosure raises the source line of unselected cells to V_{dd} instead of ground thereby maintaining low sub-threshold leakage in both dynamic as well as standby modes. The source line voltage is derived as the complement of the wordline.

In one embodiment, the present disclosure provides a Read Only Memory (ROM) device containing a plurality of memory cells accessed through a plurality of wordlines and a plurality of bitlines. Each of the memory cells includes a first main terminal of a controlled switch connected to one of the plurality of bitlines of the memory cell. A control terminal of the controlled switch is connected to one of the plurality of wordlines of the memory cell. Each of the memory cells also includes a second main terminal of the controlled switch connected to the complement of the wordline if the memory cell stores a “0”. On the other hand, the second main terminal is left unconnected if the memory cell stores a “1”.

In another embodiment, the present disclosure provides a Read Only Memory (ROM) device. The ROM device includes a plurality of memory cells accessed through a plurality of wordlines and a plurality of bitlines. The memory cell includes a controlled switch. The controlled switch includes a first main terminal of the controlled switch connected to one of the plurality of bitlines of the memory cell. The control terminal of the controlled switch is connected to one of the plurality of wordlines of the memory cell. The second main terminal of the controlled switch connected to the complement of the wordline if the memory cell stores a “0”. On the other hand, the second main terminal is left unconnected if the memory cell stores a “1”.

In still another embodiment, the present disclosure provides a method for creating a Read Only Memory (ROM) device. The method includes providing a controlled switch. The method also includes connecting a first main terminal of the controlled switch to the bitline of the memory cell. The method also includes connecting the control terminal of the controlled switch to the wordline of the memory cell. The method further includes connecting the second main terminal of the controlled switch to the complement of the wordline if the memory cell stores a “0”, and leaving the second main terminal unconnected if the memory cell stores a “1”.

Other technical features may be readily apparent to one skilled in the art from the following figures, descriptions and claims.

### BRIEF DESCRIPTION OF THE DRAWINGS

For a more complete understanding of this disclosure and its features, reference is now made to the following description, taken in conjunction with the accompanying drawings, in which:

FIG. 1 is a conventional ROM array (n×m) structure with corresponding wordline, sourceline and bitline supplies at the Gate, Source and Drain;

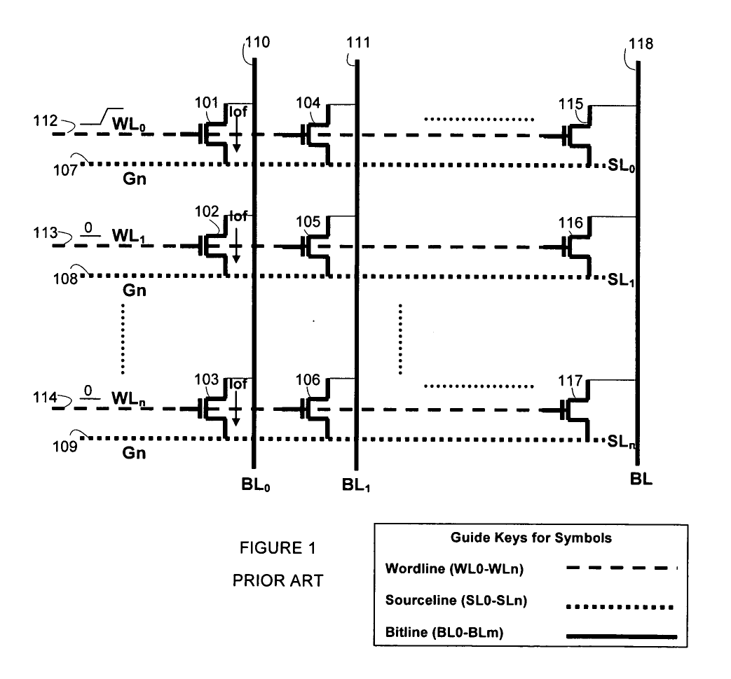

FIG. 2 is a conventional modified ROM array structure with corresponding supplies wordline, sourceline and bitline at the Gate, Source and Drain; and

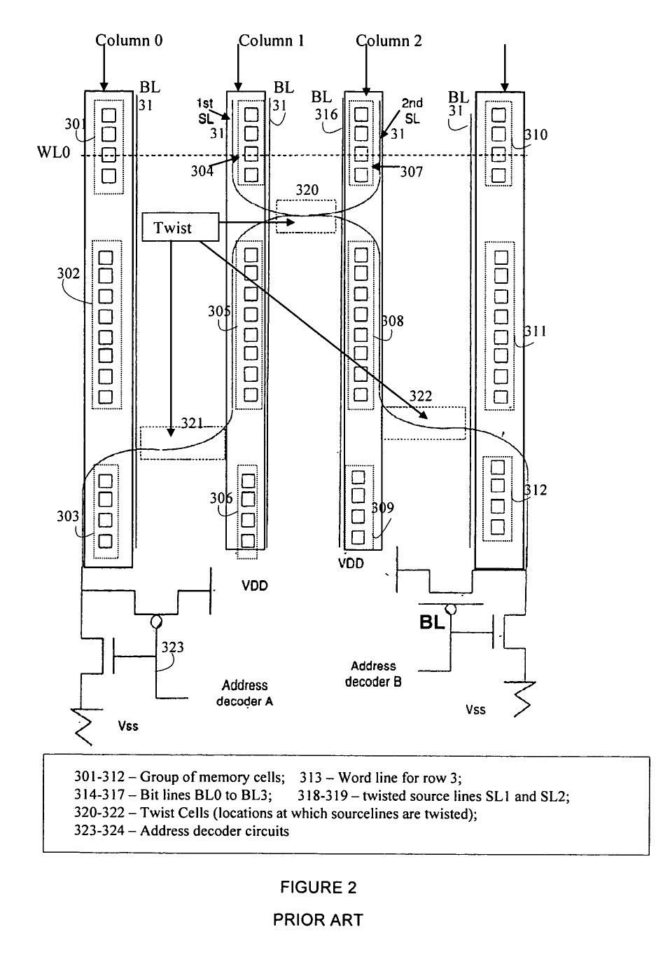

FIG. 3 is a ROM array structure and corresponding wordline, sourceline and bitline supplies at the Gate, Source and Drain according to one embodiment of the present disclosure.

### DETAILED DESCRIPTION

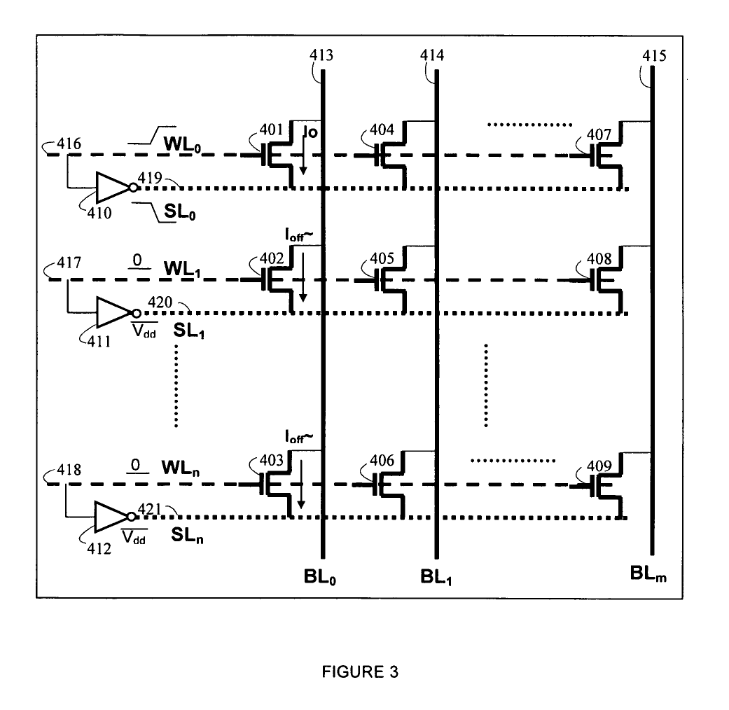

FIG. 3 illustrates one embodiment of a ROM array modified according to the present disclosure. In this embodiment, the controlled switches are NMOS transistors. The source line (419-421) is derived as the complement (410-412) of wordline (416-418). Hence the gate and source of any cell (401-409) are always at different logic levels (either V_{DD} or Gnd) depending on whether or not the cell is accessed. For a selected (401) cell, when the wordline (416) is high, the source line (419) gets pulled low. If the cell stores a “0” the NMOS transistor is turned ON and discharges the bitline (413). On the other hand, if the cell stores a “1” then the bitline does not discharge as the source of the cell is not connected to the source line that has gone low.

The source voltage (V_{SL}) is crucial for reducing the I_{SUB} as the latter highly depends on V_{gs}, V_{ds} and Vₜₕ (which depends on bulk-bias). If the source potential is held above ground we have the combined effect of all these factors to reduce the resultant leakage. For the accessed cells V_{SL} should be at ground to allow discharge current in case of a stored “0”. When the source potential of the non-accessed transistors sharing a bitline is raised to a positive voltage Vs, the V_{GS} and V_{BS} for the transistors gets negative, and V_{DS} also decreases.

From Equations 1 and 2 it is noted that when Vs increases and V_{bs} increases, Vₜₕ increases (from Equation 2). This is called body effect and as Vₜₕ increases it reduces I_{SUB}. In another situation, as Vs increases and V_{gs} decreases, I_{SUB} reduces exponentially (from Equation 1). In still another situation, as Vs increases and V_{ds} decreases, I_{SUB} reduces exponentially (from Equation 1); also reduced V_{DS} increases Vₜₕ (from Equation 2) which further reduces I_{SUB} exponentially (from Equation 1) (this reduces the DIBL effect).

The present disclosure thus proposes to make the source line of the ROM cell V_{DD} instead of ground in one embodiment. In the standby mode, both—the source line and the bitline—are pulled up to V_{DD}. Hence there is no sub-threshold leakage. In the dynamic operation mode, when a programmed cell is read, the Source line (SL) for this cell dynamically goes low while other source lines remain at V_{DD}. The unselected ROM cells sharing the same bitline, storing a “0” (being connected to their respective source lines) have their gate voltage (WL) as Gnd and the source at V_{DD} resulting in negligible sub-threshold leakage.

This arrangement facilitates the fabrication of large size ROMs with improved robustness and higher density. Earlier ROM architectures supporting up to 256 or 512 cells per bitline required a hierarchical bitline design with more than one metal layer depending on whether the bitlines are local and global. This makes the architecture complex and incurs an area penalty.

The proposed approach also improves the speed performance of the memory. Sensing time (WL generation to the BL discharge until the level when it can be sensed) is a major part of the access time of the ROM. Current ROM architectures employ sense amplifiers capable of fast sensing even small voltage difference. These sense amplifiers can be categorized as an unbalanced sense amplifier or as a balanced sense amplifier.

Unbalanced Sense Amplifier

In an unbalanced sense amplifier according to one embodiment of the present disclosure, each ROM cell has a single bitline. The absence of a complementary bitline is compensated by tying the other amplifier input at V_{DD}, a fixed value, and sensing the imbalance between the two sides of the amplifier. If the BL level decreases by even a small amount from V_{DD} level (due to leakage or coupling) the amplifier responds with a “1”.

The unbalanced status of the sense amplifier during Read1 operation, in presence of leakage and coupling noise, further creates a penalty in Read0 operation as the BL is required to discharge by a greater value to overcome the imbalance. The greater the leakage, the more is the imbalance and more will be the time taken for the BL discharge in the case of a read “0” operation. As a result, the speed performance of the memory is degraded. Besides this intentional imbalance, some margins in offset are required for fabrication mismatch in sense amplifier devices.

Balanced Sense Amplifier

In a balanced sense amplifier according to one embodiment of the present disclosure, the offset is just due to the fabrication mismatch in sense amplifier devices. A reference bitline feeds the other input of the sense amplifier that discharges through half memcell current. The time to create the differential signal level between the bitline and ref bitline (more than the offset of sense amplifier) is proportional to the bitline leakage time during Read1 operation. Thus, the speed performance of the memory degrades if the leakage is high. Hence with the proposed chip configuration, by reducing the leakage values substantially, we can gain in performance irrespective of the sensing technique.

Table 1 provides comparative data for sub-threshold leakage improvement, based on silicon models, for the conventional configuration and the proposed scheme. The PVTs taken are the worst case corners for sub-threshold leakage with max supported temperature. ROM cell dimensions and fabrication technologies were as follows—Source programmable in 65 nm technology with w=0.15 μm and 1=0.06 μm and Drain programmable in 90 nm technology with w=0.2 μm and 1=0.1 μm.

TABLE 1
Comparative Data for Sub-threshold Leakage

| | | Off current | | Off current | |
|---|---|---|---|---|---|
| | | Conventional | | Present Disclosure | Reduction |
| Technology | PVT | (source at gnd) | | (source at VDD) | Factor |
| 65 nm GP | 0.8V_FFA_125C | 275 | nA | 0.60 nA | 458 |
| SVT | | | | | |
| 65 nm LP | 0.9V_FFA_150C | 13.29 | nA | 0.51 pA | 26,058 |
| SVT | | | | | |
| 90 nm GP | 0.8V_FFA_125C | 134.31 | nA | 0.98 pA | 1,37,051 |
| SVT | | | | | |
| 90 nm GP | 0.8V_FFA_125C | 24.94 | nA | 0.92 pA | 28,195 |
| HVT | | | | | |

Though embodiments of the present disclosure have been described with reference to certain preferred embodiments, it is not exclusively limited to the particular embodiments described herein. For example, the described memory chip configuration can have other variations and probable embodiments. The proposed configuration is not constrained by the size and geometries of memory chips, cell densities, complex memory structures or the fabrication technologies.

It may be advantageous to set forth definitions of certain words and phrases used in this patent document. The term “couple” and its derivatives refer to any direct or indirect communication between two or more elements, whether or not those elements are in physical contact with one another. The terms “include” and “comprise,” as well as derivatives thereof, mean inclusion without limitation. The term “or” is inclusive, meaning and/or. The phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A Read Only Memory (ROM) device containing a plurality of memory cells accessed through a plurality of wordlines and a plurality of bitlines, each of the memory cells comprises:
a first main terminal of a controlled switch connected to one of the plurality of bitlines of the memory cell, wherein a control terminal of the controlled switch is connected to one of the plurality of wordlines of the memory cell; and
a second main terminal of the controlled switch connected to the complement of the wordline if the memory cell stores a “0”, the second main terminal being left unconnected if the memory cell stores a “1”.

2. The ROM device according to claim 1, wherein the controlled switch is an NMOS transistor.

3. The ROM device according to claim 1, wherein the complement of the wordline is a source line.

4. The ROM device according to claim 1 further comprising:
an unbalanced sense amplifier to sense a voltage difference in the ROM device.

5. The ROM device according to claim 1 further comprising:
a balanced sense amplifier to sense a voltage difference in the ROM device.

6. The ROM device according to claim 1, wherein the ROM device is an integrated chip.

7. A Read Only Memory (ROM) device comprising:
a plurality of memory cells accessed through a plurality of wordlines and a plurality of bitlines, the memory cell having a controlled switch, wherein the controlled switch comprises:
a first main terminal of the controlled switch connected to one of the plurality of bitlines of the memory cell, wherein a control terminal of the controlled switch is connected to one of the plurality of wordlines of the memory cell; and
a second main terminal of the controlled switch connected to the complement of the wordline if the memory cell stores a “0”, the second main terminal being left unconnected if the memory cell stores a “1”.

8. The ROM device according to claim 7, wherein the controlled switch is an NMOS transistor.

9. The ROM device according to claim 7, wherein the complement of the wordline is a source line.

10. The ROM device according to claim 7 further comprising:
an unbalanced sense amplifier to sense a voltage difference in the ROM device.

11. The ROM device according to claim 7 further comprising:
a balanced sense amplifier to sense a voltage difference in the ROM device.

12. The ROM device according to claim 7, wherein the ROM device is an integrated chip.

13. A method for creating an improved Read Only Memory (ROM) device, the method comprising:
providing a controlled switch;
connecting a first main terminal of the controlled switch to the bitline of the memory cell;
connecting the control terminal of the controlled switch to the wordline of the memory cell; and
connecting the second main terminal of the controlled switch to the complement of the wordline if the memory cell stores a “0”, and leaving the second main terminal unconnected if the memory cell stores a “1”.

14. The method according to claim 13, wherein the controlled switch is an NMOS transistor.

15. The method according to claim 13, wherein the complement of the wordline is a source line.

16. The method according to claim 13 further comprising:
sensing a voltage difference in the ROM device using at least one of: an unbalanced sense amplifier and a balanced sense amplifier.

17. The method according to claim 13 further comprising:
reducing noise during read operations of the ROM device.

18. The method according to claim 17, wherein reducing the noise is accomplished by controlling the bitline leakage current.

19. The method according to claim 17, wherein reducing the noise increases the speed of at least one of the memory cells.

20. The method according to claim 13, wherein the ROM device is an integrated chip.
